(19) United States
(12) Patent Application Publication
(10) Pub. No.: US 2005/0202574 A1
(43) Pub. Date: Sep. 15, 2005

(54) Vehicle inner covering part having a metal structure

(75) Inventors: Michael Wilfert, Mistelgau (DE); Rainer Fick, Weidenberg (DE); Wolfram Weiskopf, Emtmannsberg (DE)

Correspondence Address: WOOD, PHILLIPS, KATZ, CLARK & MORTIMER, 500 W. MADISON STREET, SUITE 3800, CHICAGO, IL, 60661, US

(73) Assignee: novem car interior design Metalltechnik GmbH

(21) Appl. No.: 11/079,628

(22) Filed: Mar. 14, 2005

(30) Foreign Application Priority Data
Mar. 15, 2004 (EP) 04 101 058.8

(51) Int. Cl. H01L 31/119

(52) U.S. Cl. 438/3

(57) ABSTRACT

An inner covering part for a vehicle is disclosed with a method for producing it. A two-dimensional, fluid-permeable metal structure is used and processed with a barrier layer for limiting penetration of additional or further layers through the metal structure.

### TECHNICAL FIELD

The present invention relates to a method for producing a vehicle inner covering part and to the part itself.

### BACKGROUND OF THE INVENTION

It is known to use inner covering parts having diverse decorative surfaces in vehicles. For such inner covering parts, material surfaces are used that, besides more functional aspects as light-fastness, resistance against certain substances, washability and the like, have to fulfil special aesthetic requirements. Very commonly used are inner covering parts having aluminum surfaces and wood surfaces or wood imitation surfaces.

It is further known to produce such inner covering parts in the form of a plurality of mutually connected layers. Usually, additional layers are deposited onto a carrier structure of metal or plastic (synthetic resin), which carrier structure is, in the built-in condition, to be arranged on the face opposite to the inner space of the vehicle and has specially adapted structure elements for mounting. Namely wood or aluminum layers can be deposited by gluing. These can be coated by further protective layers, e.g. lacquer layers.

It would be desirable to have an increased degree of freedom in designing vehicle inner covering parts.

### SUMMARY OF THE INVENTION

An aspect of the invention relates to a method for producing a vehicle inner covering part. According to this method, a two-dimensional metal structure which is transversely fluid-permeable is connected with a barrier layer and is connected with a further (i.e., additional) layer. The barrier layer limits a penetration of the additional or further layer through the metal structure. According to a form of the invention, a method for producing an inner covering part comprises the steps of:
providing a transversely fluid-permeable metal structure;
adhering a barrier layer to said metal structure at least temporarily; and
adhering at least one further layer to at least one of the following: said metal structure and said barrier layer; wherein said barrier layer limits penetration of said at least one further layer through said metal structure.

Another aspect of the invention relates to a correspondingly produced inner covering part itself.

The invention is based on the idea that the aesthetic effect of inner covering parts can be increased substantially by structuring metal surfaces. Thus, in the method and the inner covering part of the invention, metal structures are used, that are formed in a more complicated manner than a simple flat metal sheet. Namely, the invention relates to metal structures that are in some sense permeable at least transversely to their extension, i.e., are permeable for fluids. Examples are wire structures, especially wire meshes or fabrics, especially woven fabrics, expanded metal structures and other perforated metal structures, e.g. by means of punching or other techniques.

Such metal structures can have a substantial aesthetic appeal, whereas the invention relates also to such cases in which the metallic surface of the metal structure itself is no more visible, e.g. because of being lacquered or non-transparently coated in another manner.

In such permeable metal structures, the invention proposes to use a barrier (or sealing) layer to inhibit that during production material of other layers being flowable at least in certain production phases (including semi-fluid or viscous, such as during expansion) penetrates through the metal structure in a non-controlled manner. Therein, depending on the embodiment, the barrier layer can allow the material to penetrate into (or engage) the metal structure. This aspect will be discussed in more detail below.

According to a preferred embodiment of the invention, the metal structure is visible as such, i.e., as lacquered, covered, or embedded in a transparent manner, if at all. Therein, the aesthetic appeal of the metal gloss can appear. Further, it is preferred that the metal structure is somewhat transparent, namely that a layer thereunder is visible. This can be a lower wood layer or a metal layer. Especially, the barrier layer can also serve as a bonding agent layer between a decoration layer, such as of wood or aluminum, and the metal structure. The barrier layer can be designed such that it does almost not appear optically due to its material thickness or low degree of coloring or colourlessness. It will be discussed in more details below that in such embodiment of the invention, a wood or metal layer can have the function of the barrier layer itself.

Further, it is preferred that a carrier structure of the inner covering part is cast-on or injection-molded on the compound of the metal structure in the barrier layer and optional further (i.e., additional) layers. Especially relevant is the case that the barrier layer serves for inhibiting a penetrating of the carrier structure material flowable during casting-on or injection-molding, especially in the case of a thermoplast, into the metal structure. Thus, in this case the barrier layer is arranged on the same side of the metal structure as the carrier structure.

The barrier layer can be connected to the metal structure such that it only adheres thereto. However, preferred are embodiments in which the barrier layer, by means of an at least partial softening, is at least partially pressed into the metal structure and thus connects to the metal structure in an especially strong way. A preferred material for the barrier layer is polyamide foil. Naturally, the metal structure can be pre-treated in diverse manners for a good adhesion. Lacquers, chromatin, conversion treatments and the like are contemplated.

The connection between the barrier layer and a layer thereunder, especially a carrier structure, can be a mere glue connection, especially by means of a dry gluing or tacking foil. However, a two-component polyurethane glue material or another gluing technique can also be used.

Preferably, the metal structure is connected to the barrier layer and the carrier structure and optional further (i.e., additional) layers between the barrier layer and the carrier structure in one integral process step, especially in a heated mold. Therein, the mold can be used as a cutting tool during closing. In this invention, however, it is preferred to do this for centering tongues for centering the respective layers in the mold, if at all, and to cut the (rest of the) layers near to the final form so that they fit into the mold already during introduction therein.

According to one embodiment of the invention, a carrier structure is injection-molded onto or cast-onto the face of the metal structure opposite to the barrier layer. In this case, the carrier structure material will penetrate comparatively far into the metal structure or even almost penetrate through the metal structure since the barrier layer will normally not completely penetrate through the metal structure. The barrier layer can be taken off in a later processing step so that the metal structure is visible on the carrier structure material completely or in form of only those parts projecting over the carrier structure material, as desired.

Therein, the barrier layer must thus be connected to the metal structure. In many cases, a pre-forming will be necessary before injection-molding or casting-on. It is preferred to conduct the steps of connecting the barrier layer to the metal structure and of pre-forming in one integral process step in a heated tool, compare the above-mentioned mold. Alternatively, the barrier layer can be rolled-onto the metal structure, or the barrier layer in the metal structure can be connected as respective board material.

In one aspect of this embodiment, the compound of the metal structure and the barrier layer can be provided with a respective layer injection-molded thereon or cast thereon on both sides, wherein one side is transparent and the other side serves as a carrier or is to be mounted to a carrier. Primarily, the injection-molding or casting-on is done at the face of the metal structure opposite to the barrier layer, the barrier layer is removed thereafter, and the thus exposed face is provided with a further layer, again. Especially, the transparent layer can be a cast-on layer and the further layer can be an injection-molded carrier structure. Preferably, the injection-molding is done first and the casting after removing the barrier layer.

A further aspect is to provide a wood layer, aluminum layer, or another decoration layer as a barrier layer onto a partially transparent metal structure and to provide an injection-molded or cast-on transparent layer on the opposed side thereafter. Therein, the transparent layer penetrating the metal structure up to the decoration layer can be used as a bonding agent between the decoration layer and the metal structure. Therein, the barrier layer thus only serves for inhibiting an uncontrolled penetration of a flowable layer material through the metal structure wherein, however, the transparent layer almost completely embeds the metal structure.

The decoration layer can already be a carrier structure itself or be connected with a carrier structure.

The description above mentions various layers, especially the metal structure and the barrier layer wherein these terms do not necessarily mean that these layers extend over the complete area of the inner covering part. Interesting decoration effects can also be achieved if e.g. the metal structure is only in a part of the area or the barrier layer is only in a part of the area and the metal structure is penetrated by another layer material in the rest. Also in this manner, the metal structure can be partially visible.

### BRIEF DESCRIPTION OF THE DRAWINGS

FIGS. 1-3 are schematic sectional views of a mold tool used in the production of an inner covering part according to the invention, and

FIGS. 3-9 are schematic sectional views illustrating further embodiments.

### DETAILED DESCRIPTION OF THE PREFERRED EMBODIMENTS

In the following detailed description, preferred embodiments of the invention are explained in detail and as examples only. The individual features can be relevant for the invention also in other combinations. Also the following detailed description refers to the product character as well as to the method character of the invention.

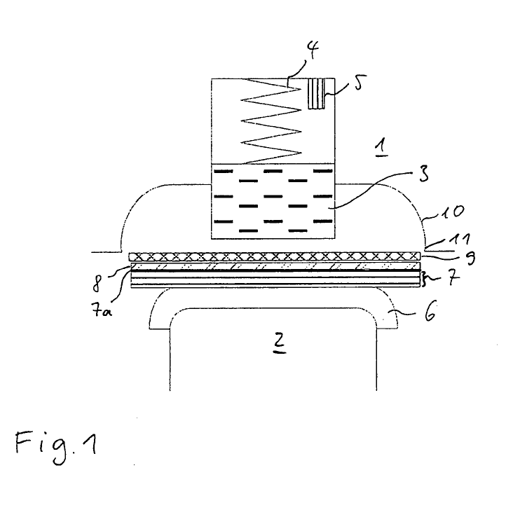

FIG. 1 shows a heatable mold tool for producing an inner covering part according to the invention. The mold tool comprises an upper part (matrix) 1 and a lower part (die) 2 having respective mold faces, wherein upper part 1 can be vertically moved down onto lower part 2. A leading, displaceable mold member or ram, i.e., a vertically displaceably supported ram 3, is mounted in upper part 1. FIG. 1 shows that leading ram 3 is vertically pre-loaded by a spring 4. Spring 4 can actually be implemented, e.g., by a pressure fluid cylinder, e.g., for implementing non-linear characteristic curves of power development as desired.

Further, a stop 5 is provided limiting the path of leading ram 3 in an upward direction. FIG. 3 shows in more details that this is done in such manner that the lower face of leading ram 3 is flush with the mold face of upper part 1.

In this embodiment, a bent sheet metal part 6 is laid on lower part 2 as a carrier structure. Sheet metal part 6 is pre-bent in this embodiment because it is provided with special fastening elements that can not be produced in one integral forming step together with layers 7, 8, and 9 and prohibit a bending of sheet metal part 6 together with these layers.

A layer arrangement 7 of wood laminate layers lies on sheet metal carrier structure 6 in a planar manner, which arrangement 7 supports a barrier layer 8, namely a polyamide lining foil thereon. Further, a (woven) wire mesh 9 as a metal structure according to the invention lies on barrier layer 8.

Besides that, layers 7, 8, and 9 are readily cut and thus fit into the mold and fit to the desired geometry of the inner covering part. Only the centering tongues mentioned above can be squeezed of or cut of by a squeezing edge.

The mold face of upper part 1 has, in its border region, a lowering profile 10 and said squeezing edge. The lowering profile is numerated with 10 and the squeezing edge with 11.

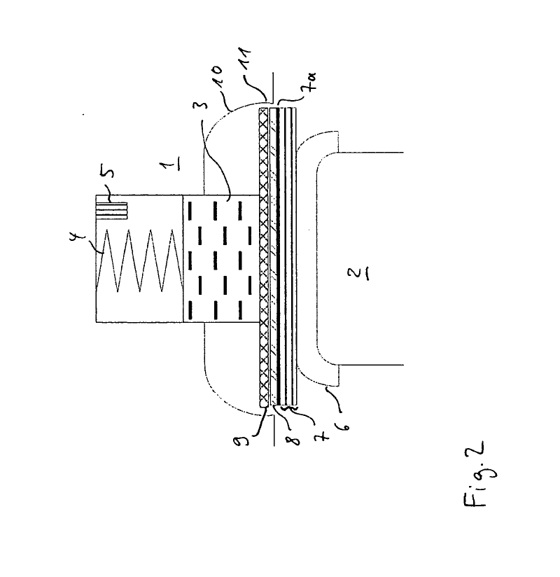

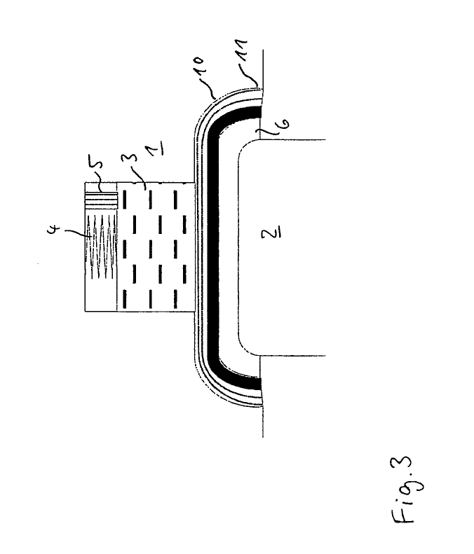

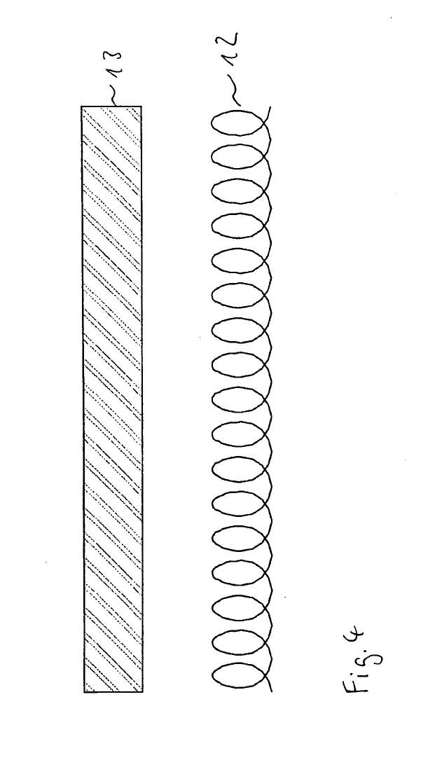

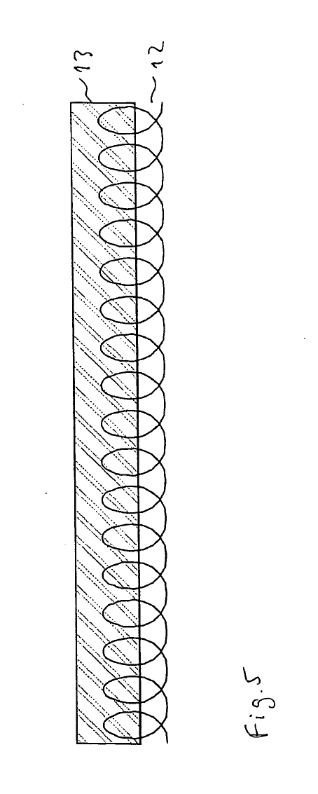

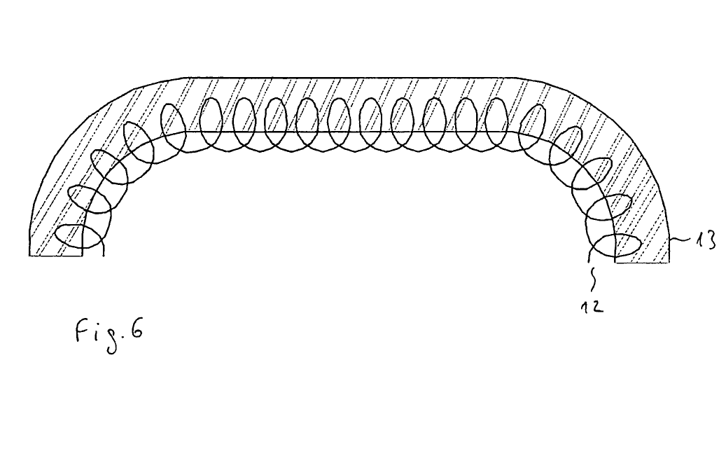

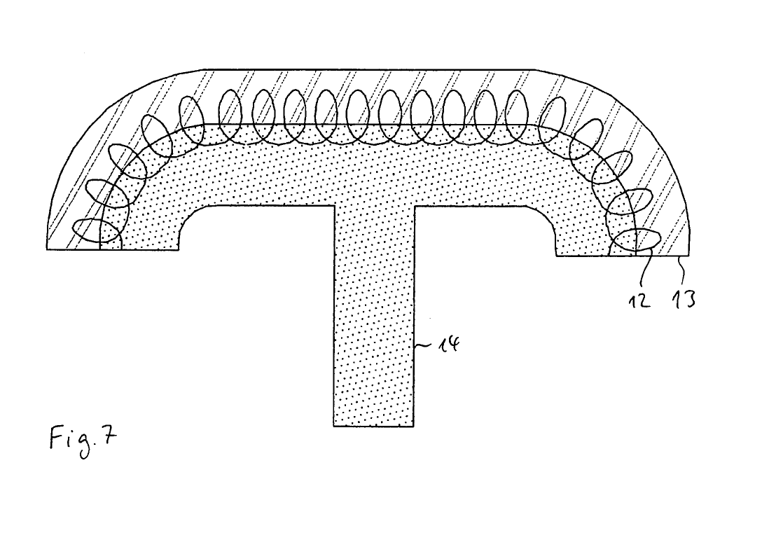

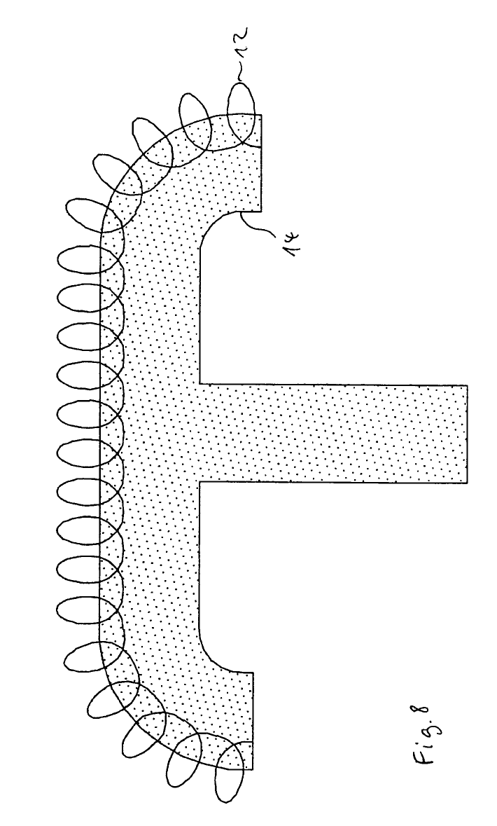

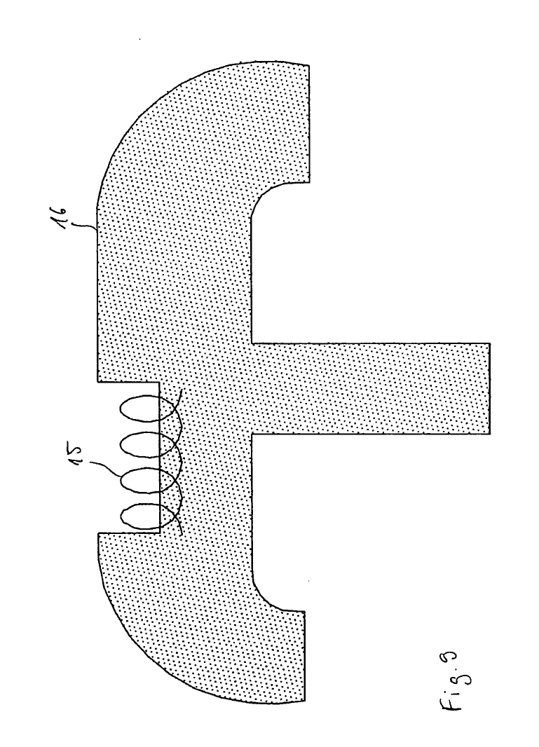

FIGS. 2 and 3 show a similar schematic illustration of the mold tool wherein in FIG. 2 upper part 1 has been moved down such that leading ram 3 abuts against and fixes metal structure 9 to its place by means of the load of spring 4 or a pressure fluid cylinder instead thereof. Further, the lower face of leading ram 3 coming into contact with metal structure 9 can be roughened somewhat as long as impressions on the metal structure affecting the decorative function do not result.

In the phase from FIG. 1 to FIG. 2, layer 7, 8, and 9 are fixed by known centering pins of the mold tool engaging into corresponding centering tongues of layers 7, 8, and 9 (not shown here).

FIG. 3 shows a further step in which upper part 1 is moved down onto lower part 2 such that layers 7, 8, and 9 are pressed onto the shape of carrier structure 6 or lower part 2 and are press-laminated by pressure and a forming temperature of approximately 160° C. A dry tacking foil 7a is provided between carrier layer 8 and wood laminate layer arrangement 7. A dry tacking foil is further provided between wood laminate layer arrangement 7 and carrier structure 6, however not shown. Wood laminate layer arrangement 7 can further be pre-treated for improving the adhesion properties. Both barrier layer 8 and dry tacking foil 7a are chosen such that they almost not appear optically and do not affect the decorative effect of the wood decoration of arrangement 7.

The lowering profile 10 together with the profile of squeezing edge 11 serves for an especially strong pressing of the arrangement in this region (what is not shown in detail) and for pressing metal structure 9 into barrier layer 8. On the other hand, it is important with regard to the geometry, that an inclination of 3° for removal from the mold is provided. Squeezing edge 11 also has a slight inclination to the inside such that the completed inner covering part can be removed from mold upper part 1. The border region of the inner covering part affected by this strong pressing is not visible in the condition of mounting in the vehicle.

Forming is done mainly by bending (instead of deep-drawing) in order to avoid a mesh draft in metal structure 9 and to maintain the mesh apertures in a homogenous condition.

After opening the mold tool after sufficient time has passed, the completed inner covering part can be taken out. This part shows an aesthetically appealing metal structure surface 9, the wood decoration of wood laminate arrangement 7 also being visible therethrough and through the substantially transparent lining foil barrier layer 8 and the dry tacking foil. Modifications can be stainless steel or aluminum wire meshes in open or non-transparent version or stainless steel or aluminum expanded metal structures, the surfaces of which can be anodized, colored or lacquered.

The polyamide lining foil not only serves as barrier layer for inhibiting a penetration of the dry tacking foil into the metal structure and thus an optical affection. The polyamide lining foil further provides a bonding agent effect by good gluing properties on the one hand and a good adhesion and further mechanical engagement after press-bonding with the metal structure on the other hand.

The completed design element can be lacquered thereafter, if desired, and can also be embedded or poured-in with the (decoration) upper side in a transparent manner. Further, it is reasonable to protect the completed decoration surface with a protection foil in order to avoid damages during transport and mounting in the vehicle. This protection foil can already be introduced into the mold tool shown in FIGS. 1 to 3.

In individual cases barrier layer 8 can also be visible as a design element. The depth of press-penetration is determined beside the geometric details of metal structure 9 by the foil thickness of polyamide foil 8, by the pressure and by the distance between upper tool part 1 and lower tool part 2 as well as the temperature.

The post treatment can include a grinding of edges, a coating by e.g. a glued-on felt (also for acoustic protection) and by the provision of a sealing bead of glue. Also, the border can be edge-formed and a backside coverage can be mounted, thereby avoiding grinding.

FIGS. 4 to 8 schematically illustrate a further embodiment. According to FIG. 4, a metal structure 12, here a symbolically shown wire mesh, is coated with a barrier layer, namely a polyamide lining foil 13. This can be done by warm rolling-on by uncoiling or in the form of board material. Therein, polyamide barrier layer 13 penetrates somewhat into metal structure 12, as shown in FIG. 5. The corresponding compound is formed as desired, as shown in FIG. 6. This can be done in a similar mold tool as shown in FIGS. 1 to 3. Especially the connection of layers 12 and 13 together with the forming step can be done in one integral step.

The connection with the barrier layer stabilizes the compound for following process steps and, further, allows a fixing by sucking in a mold tool similar to FIGS. 1 to 3.

Thereafter, a thermoplastic carrier structure, designated with 14, can be injection-molded onto the still exposed face of wire mesh metal structure 12 in a manner known as such. The thermoplastic material penetrates into wire mesh 12 in the exposed region. A pin shown in FIG. 7 shall symbolize a form element by which the inner covering part can be mounted in a vehicle. Corresponding form elements can also be part of an inner covering part produced according to FIGS. 1 to 3.

FIG. 8 shows the structure of FIG. 7 wherein, however, polyamide barrier layer 13 has been removed. As long as it has not engaged the wire mesh too strongly, it can simply be drawn-off.

Thus, a complete inner covering part can be produced in an especially simple manner and be further processed or mounted conventionally.

However, as an example, also a transparent layer for embedding wire mesh 12 can be deposited onto the structure shown in FIG. 8 and produced as described above, especially by embedding or pouring-in. This further structure is not shown in FIG. 8, however, would essentially be different in that wire mesh 12 is embedded in a transparent manner.

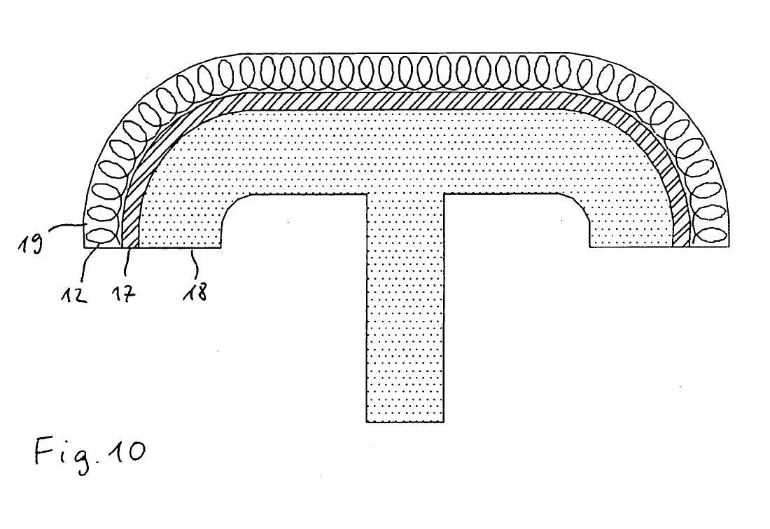

FIG. 9 illustrates symbolically that the metal structure, here designated with 15, does not necessarily need to extend over the complete area of inner covering part 16. It can also be a decoration inlay. Referring to the examples of FIGS. 4 to 8, also barrier layer 13 would have to be sized in its area as metal structure 15. Further, it is of course possible (but not shown here) to expose only a part of the metal structure, e.g. in that the barrier layer is smaller than the metal structure. Further, in principle, also different penetration depths of the barrier layer into the metal structure can be used, namely on different places of the same inner covering part, if desired decoration effects can be achieved thereby. Especially barrier layers of different thermoplasts can provide different penetration depths and thus differently exposed areas of the metal structure.

Besides that, the explanations relating to the first embodiment apply, especially in view of the cutting close to the final form.

FIG. 10 shows a further embodiment of the invention. Here, a wood layer 17 is glued onto a wire mesh 12 as a barrier layer. A carrier structure 18 can be injection-molded onto wood layer 17 thereafter or at the end of the process. On the face of wire mesh 12 opposite to wood layer 17 a transparent layer 19 is cast-on that has penetrated up to wood layer 17 and has embedded wire mesh 12. Thus, wood layer 17 serves as a barrier layer here and limits the penetration of the transparent layer 19 through the wire mesh. Carrier structure 18 can also be injection-molded after the deposition of transparent layer 19.

It is apparent from the foregoing description that various modifications of the embodiments are feasible other than specifically disclosed above. The embodiments are thus only meant as examples. The scope of the invention shall be defined by the following claims.

1. A method for producing a vehicle inner covering part, said method including the steps of:
providing a two-dimensional metal structure which is transversely fluid-permeable;
connecting said metal structure with a barrier layer, and
connecting said metal structure with a further layer
wherein said barrier layer limits a penetration of said further layer through said metal structure.

2. A method according to claim 1, in which said metal structure is a wire structure, especially a wire mesh.

3. A method according to claim 1, in which said metal structure is an expanded metal layer.

4. A method according to claim 1, in which said metal structure as such is at least partially visible as a decoration element after the production of said inner covering part.

5. A method according to claim 1, in which after the production of said inner covering part said metal structure is at least partially transparent and a layer arranged below said metal structure is visible through said metal structure.

6. A method according to claim 1, in which a carrier structure of said inner covering part is injection-molded thereon or cast thereon.

7. A method according to claim 5, in which said barrier layer limits the penetration of carrier structure material through said metal structure.

8. A method according to claim 1, in which the connection between said metal structure and said barrier layer is realized by means of softening said barrier layer and at least partial pressing of said barrier layer into said metal structure.

9. A method according to claim 8, in which said barrier layer is produced from a polyamide foil.

10. A method according to claim 1, in which said barrier layer is glued to a further layer, preferably by a dry tacking foil.

11. A method according to claim 1, in which said connection of said metal structure with said barrier layer and said carrier structure of said inner covering part is implemented by one integral process step by heating in a mold.

12. A method according to claim 11, in which the layers introduced in said mold have a cut-to-size form close to the final form fitting into said mold with the exception of optional centering tongues.

13. A method according to claim 1, in which said barrier layer is connected to said metal structure and said further layer is applied onto the face of said metal structure opposite to said barrier layer.

14. A method according to claim 13, in which said connection of said barrier layer to said metal structure and a pre-forming of this compound are realized in one integral process step in a heated mold.

15. A method according claim 13, in which said barrier layer is removed after the application of the carrier structure and a further layer is applied onto the same side of the metal structure.

16. A method according to claim 13, in which a decoration layer is connected to said metal structure as said barrier layer and a transparent layer is injection-molded onto or cast onto the side of said metal structure opposite to said decoration layer.

17. A method according to claim 1, in which said metal structure extends over a part of the planar extension of said inner covering part.

18. A method according to claim 1, in which said barrier layer extends over a part of the planar extension of said inner covering part.

19. A method for producing an inner covering part, said method comprising the steps of:
providing a transversely fluid-permeable metal structure;
adhering a barrier layer to said metal structure at least temporarily; and
adhering at least one further layer to at least one of the following: said metal structure and said barrier layer; wherein said barrier layer limits penetration of said at least one further layer through said metal structure.
